(19) United States
(12) Patent Application Publication
(10) Pub. No.: US 2014/0241071 A1
(43) Pub. Date: Aug. 28, 2014

(54) Fast Power Loss Recovery By Swapping Boot and Recovery Data Sets in a Memory

(71) Applicant: SEAGATE TECHNOLOGY LLC, Cupertino, CA (US)

(72) Inventors: Ryan James Goss, Prior Lake, MN (US); David Scott Ebsen, Minnetonka, MN (US); Antoine Khoueir, Apple Valley, MN (US)

(73) Assignee: SEAGATE TECHNOLOGY LLC, Cupertino, CA (US)

(21) Appl. No.: 13/777,844

(22) Filed: Feb. 26, 2013

(51) Int. Cl. G11C 7/10

(52) U.S. Cl. CPC G11C 7/1084
USPC 365/189.05

(57) ABSTRACT

Method and apparatus for managing data in a memory. In accordance with some embodiments, a recovery data set representing a current state of a storage device is stored in a rewritable non-volatile memory responsive to detection of a potentially imminent deactivation of the device. The recovery data set is swapped with a boot data set in said memory responsive to subsequent deactivation of the device. The boot data set is subsequently used to transition the device from a deactivated mode to an operationally ready mode during device reinitialization. The boot data set is thereafter swapped with the recovery data set to return the device to the current state.

### SUMMARY

Various embodiments of the present disclosure are generally directed to managing data in a data storage device.

In accordance with some embodiments, a recovery data set representing a current state of a storage device is stored in a rewritable non-volatile memory responsive to detection of a potentially imminent deactivation of the device. The recovery data set is swapped with a boot data set in said memory responsive to subsequent deactivation of the device. The boot data set is subsequently used to transition the device from a deactivated mode to an operationally ready mode during device reinitialization. The boot data set is thereafter swapped with the recovery data set to return the device to the current state.

These and other features and aspects which characterize various embodiments of the present disclosure can be understood in view of the following detailed discussion and the accompanying drawings.

### BRIEF DESCRIPTION OF THE DRAWINGS

FIG. 1 provides a functional block representation of a data storage device in accordance with various embodiments of the present disclosure.

FIG. 2 illustrates exemplary formats for a data object and a corresponding metadata unit used to describe the data object.

FIG. 3 depicts a storage arrangement of working data, recovery data sets and boot data sets of the device of FIG. 1 in accordance with some embodiments.

FIG. 4 depicts a storage manager and respective tiers of the memory structure in accordance with some embodiments.

FIG. 5 illustrates a recovery data set generator of the storage manager of FIG. 4.

FIG. 6 represents a boot data set generator of the storage manager of FIG. 4.

FIG. 7 depicts interaction between a restore engine of the storage manager and a power monitor circuit of the data storage device.

FIG. 8 is a sequence diagram illustrating various loading and swapping operations of the boot data set and the recovery data set in accordance with some embodiments.

FIG. 9 is a flow chart for a DATA MANAGEMENT routine illustrative of steps carried out in accordance with some embodiments.

### DETAILED DESCRIPTION

The present disclosure generally relates to the management of data in a data storage device, and more particularly to improvements in the manner in which a data storage device is transitioned to an operationally ready mode.

Data storage devices generally operate to store blocks of data in memory. The devices can employ data management systems to track the physical locations of the blocks so that the blocks can be subsequently retrieved responsive to a read request for the stored data. The device may be provided with a hierarchical (multi-tiered) memory structure with different types of memory to accommodate data having different attributes and workloads.

Metadata can be generated and maintained to track the locations and status of the stored data. The metadata tracks the relationship between logical elements (such as logical block addresses, LBAs) stored in the memory space and physical locations (such as physical block addresses, PBAs) of the memory space. The metadata can also include state information associated with the stored data and/or the memory location of the stored data, such as the total number of accumulated writes/erasures/reads, aging, drift parametrics, estimated or measured wear, etc.

Upon initialization of a storage device, or a larger user system of which the storage device forms a part, it is common for an initialization (boot) sequence to be carried out to transition the system from a deinitialized mode to an operationally ready mode. During the boot sequence, various operational files, user data, metadata and other control information are loaded and/or transferred to configure the system for normal operation. Depending on the complexity of the operational environment, a relatively long and extensive boot/recovery sequence may be required.

Various embodiments of the present disclosure accordingly provide improvements in the manner in which a system may be reinitialized to an operationally ready mode. As explained below, some embodiments employ a storage device with a rewritable non-volatile memory location. The memory location may constitute a selected tier in a multi-tier memory structure.

A recovery data set adapted to represent a then current state of the storage device is generated in response to the detection of a potentially imminent deactivation of the storage device. The recovery data set is loaded to the memory location. Should deactivation of the device not subsequently occur, the recovery data set may be no longer needed and may be jettisoned from the memory location.

If the device is deactivated, a data swap takes place as the device shuts down so that the recovery data set is replaced with a boot data set in the memory location. The boot data set is adapted to provide data used during a subsequent boot operation which occurs during subsequent reinitialization of the device. Once the boot operation is completed, the boot data set is swapped with the recovery data set to return the data storage device to the previously current state prior to the deactivation event.

The use of rewritable non-volatile memory cells allows the respective recovery and boot data sets to be quickly swapped as required without the need for an intervening erasure operation to reset the memory cells prior to receipt of the new data.

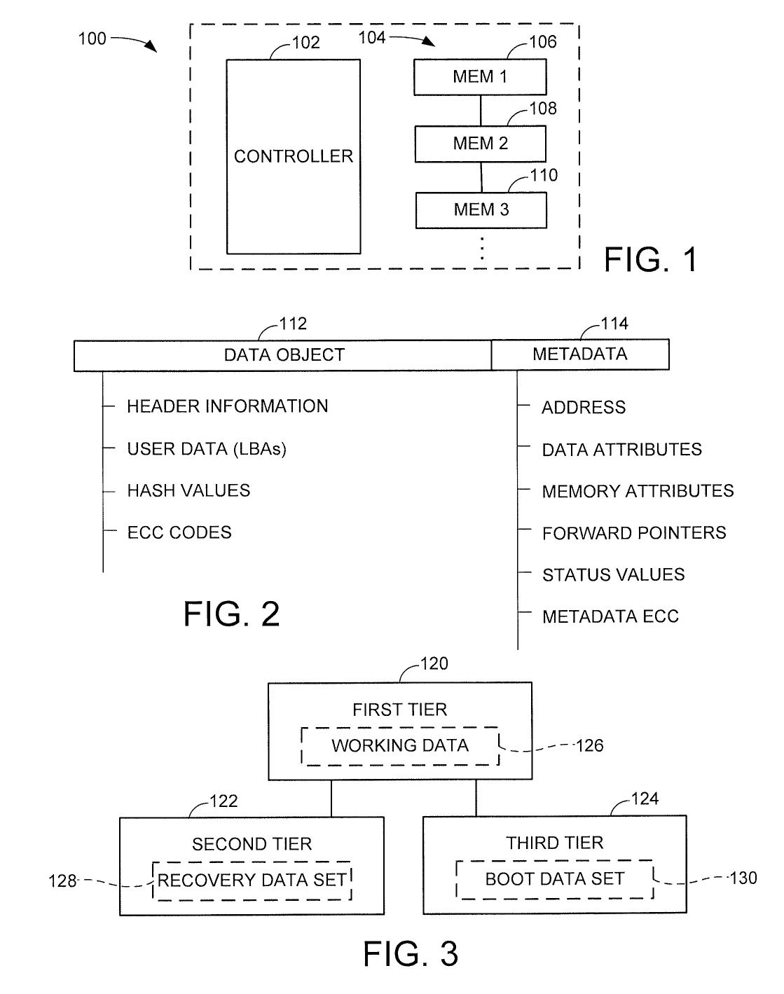

These and other features of various embodiments can be understood beginning with a review of FIG. 1 which provides a functional block representation of a data storage device 100. The device 100 includes a controller 102 and a multi-tiered memory structure 104. The controller 102 provides top level control of the device 100, and the memory structure 104 stores and retrieves user data from/to a requestor entity, such as an external host device (not separately shown).

The memory structure 104 includes a number of memory tiers 106, 108 and 110 denoted as MEM 1-3. The number and types of memory in the various tiers can vary as desired. Generally, the higher tiers in the memory structure 104 may be constructed of smaller and/or faster memory and the lower tiers in the memory structure may be constructed of larger and/or slower memory. Other memory configurations are envisioned, including memory arrangements with a single tier, a memory arrangement with a non-volatile cache and a non-volatile main memory, etc.

For purposes of providing one concrete example, the system 100 is contemplated as a flash memory-based storage device such as a solid state drive (SSD), a portable thumb drive, a memory stick, a memory card, a hybrid storage device, etc. adapted to be coupled to a user device such as a computer or other electronic device. The use of flash memory provides erasable main memory data storage at a lower tier in the memory structure. One or more higher tiers in the memory structure can comprise rewriteable non-volatile memory such as resistive random access memory (RRAM), phase change random access memory (PCRAM), spin-torque transfer random access memory (STRAM), etc. This is merely illustrative and not limiting. Other levels may be incorporated into the memory structure, such as volatile or non-volatile cache levels, buffers, etc.

FIG. 2 illustrates exemplary formats for a data object 112 and associated metadata 114 that can be used by the device 100 of FIG. 1. Other formats may be used. The data object 112 is managed as an addressable unit and may be formed from one or more data blocks supplied by the requestor (host). The metadata 114 provide control information to enable the device 100 to locate and retrieve the previously stored data object 112. The metadata will tend to be significantly smaller (in terms of total number of bits) than the corresponding data object to maximize data storage capacity of the device 100.

Depending upon the format, the data object 112 may include a variety of different types of data including header information, user data, one or more hash values and error correction code (ECC) information. The user data may be in the form of one or more data blocks each having a logical address, such as a logical block address (LBA) used to identify the data at the requestor level. The header information may be the LBA value(s) associated with the user data blocks or other useful identifier information.

The hash value can be generated from the user data using a suitable hash function, such as a Sha hash, to reduce write amplification by comparing the hash value of a previously stored LBA (or range of LBAs) to the hash value for a newer version of the same LBA (or range of LBAs). If the hash values match, the newer version may not need to be stored to the structure 104 as this may represent a duplicate set of the same user data.

The ECC information can take a variety of suitable forms such as outercode, parity values, IOEDC values, cyclical correction codes such as BCH or Read Solomon codes, checksums, etc. The ECC codes are used to detect and correct up to a selected number of errors in the data object during read back of the data.

The metadata 114 may include a variety of different types of control data such as address information, data attributes, memory attributes, forward pointers, status value(s) and metadata level ECC codes. Other metadata unit formats can be used. The address information identifies the physical address of the corresponding data object, and may provide logical to physical address conversion information as well. Physical addressing may be in terms of tiers, dies, lanes, garbage collection units (GCUs), erasure blocks, rows, columns, cache lines, pages, bit offsets, and/or other address values, depending on the configuration of the memory.

The data attribute information identifies attributes associated with the data object 112, such as status, revision level, timestamp data, workload indicators, etc. The memory attribute information provides parametric attributes associated with the physical location at which the data object 112 is stored. Examples include total number of writes/erasures, total number of reads, estimated or measured wear effects, charge or resistance drift parameters, bit error rate (BER) measurements, aging, etc. These respective sets of attributes can be maintained by the controller and/or updated based on previous metadata entries.

The forward pointers are used to enable searching for the most current version of the data object 112. The status value(s) indicate the current status of the associated data object (e.g., stale, valid, etc.). The metadata ECC may provide a smaller ECC value than used in the data object and can be used to detect/correct errors in the metadata during readback.

FIG. 3 depicts first, second and third memory tiers 120, 122 and 124 of the memory structure 104. In accordance with some embodiments, working data 126 are stored in the first tier 120, one or more recovery data sets 128 are stored in the second tier 122 and one or more boot data sets are stored in the third tier 124. This is merely exemplary and not limiting, as the respective data sets represented at 126-130 can be stored in any combination of suitable tiers or other memory locations. It is contemplated that the first tier will be an upper (higher) tier in the priority order of the memory structure 104 and the second and third tiers will be relatively lower tiers with respect to the upper tier.

The working data represent normal data (both data objects 112 and/or metadata 114) used by the device 100 during normal operation. The content of the data objects may take a variety of forms and generally may represent user data stored by the requestor and retrieved thereto as required to service access commands. The user data may be in the form of operational files, data sets, documents or other data objects used by applications at the requestor or data storage device level, operating system files used at the requestor or data storage level, and so on. Depending on priority, the working data may be stored throughout the multi-tiered memory structure 104. As desired, higher priority working data may be migrated to a higher tier to facilitate transfer with the requestor.

The recovery and boot data sets 128, 130 are additional data sets that are generated by the storage device 100 for use during reinitialization efforts to restore the device 100 to a normal operational mode after a deinitialization operation, such as a power down or other anomalous event.

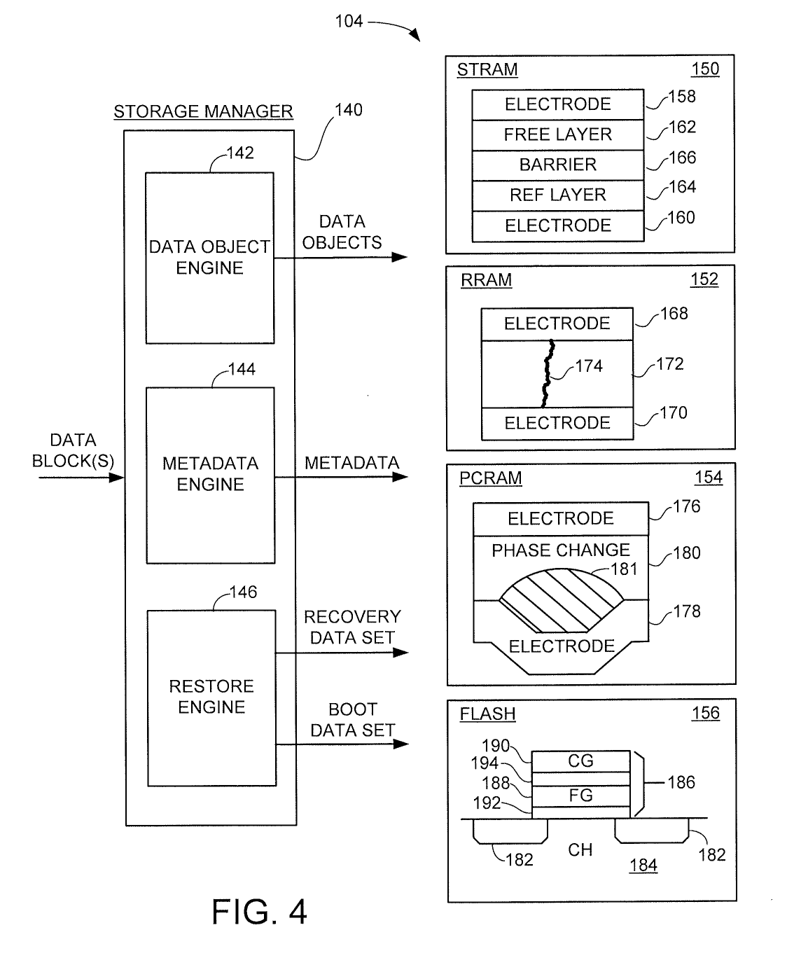

FIG. 4 depicts a storage manager 140 of the data storage device in conjunction with an example number of tiers of the memory structure 104. The storage manager 140 may be incorporated as a portion of the controller 102 and/or the memory structure 104. The storage manager 140 includes a data object engine 142 that generates data objects responsive to presentation of data blocks from the requestor. A metadata engine 144 generates metadata to describe the data objects. The respective data objects and metadata may be stored to the same, or different, tiers in the memory structure 104. A restore engine 146 generates the aforementioned recovery data set 128 and boot data set 130 and also stores these sets to one or more of the various tiers. The restore engine 146 further swaps the recovery and data sets to a selected memory location, such as an upper tier, as needed during system reinitialization as explained below.

The memory structure 104 in FIG. 4 is shown to encompass four exemplary tiers 150, 152, 154 and 156. Other formats and ordering of tiers can be used. The first tier 150 is shown to comprise spin-torque transfer random access memory (STRAM) memory cells, which are rewritable non-volatile memory cells each adapted to store data as a programmable electrical resistance. The exemplary STRAM cell includes upper and lower conductive electrodes 158, 160 which bound a magnetic tunneling junction (MTJ) formed of a free layer 162, reference layer 164 and intervening tunneling barrier layer 166. Other MTJ configurations can be used.

The free layer 162 comprises one or more layers of magnetically responsive material with a variable magnetic orientation. The reference layer 164 comprises one or more layers of magnetically responsive material with a fixed magnetic orientation. The reference layer may include a pinning layer, such as a permanent magnet, a synthetic antiferromagnetic (SAF) layer, etc., and a pinned layer, such as a ferromagnetic layer oriented magnetically by the pinning layer. The direction(s) of the magnetic orientation may be perpendicular or parallel to the direction of current through the MTJ.

The MTJ exhibits different electrical resistances in relation to the orientation of the free layer 162 relative to the reference layer 164. A relatively low resistance is provided in a parallel orientation, where the free layer is oriented in the same direction as the reference layer. A relatively high resistance is provided in an anti-parallel orientation, where the free layer is oriented in the opposing direction as the reference layer. Spin torque currents can be applied to transition the free layer between the parallel and anti-parallel orientations.

The second tier 152 comprises a non-volatile rewritable resistive random access memory (RRAM). Each RRAM cell comprises top and bottom conductive electrodes 168, 170 separated by an intervening layer such as an oxide layer or electrolytic layer. The intervening layer 172 normally has a relatively high electrical resistance.

During a programming operation, ionic migration is initiated which may result in the formation of a conductive filament 174 that lowers the electrical resistance through the RRAM element 172. Other RRAM configurations are contemplated that do not necessarily form a conductive filament, such as structures that undergo a change of state by the migration of ions or holes across a barrier or to an intermediate structure that results in a controlled change in resistance for the element.

The third tier 154 in the memory structure 104 in FIG. 4 comprises a non-volatile, rewritable phase change random access memory (PCRAM). Each PCRAM cell has top and bottom conductive electrodes 176, 178 separated a phase change material 180. The phase change material is heat responsive and transitions (melts) when heated to a temperature at or above its glass transition temperature. Depending on the rate at which the layer 180 is subsequently cooled, at least a portion of the material can take an amorphous or crystalline state, with respective higher and lower resistances. FIG. 4 shows an amorphous zone 181 indicating the cell is programmed to a high resistance state.

The fourth tier 156 is a flash memory tier made up of non-volatile, erasable flash memory cells. Doped regions 182 in a semiconductor substrate 184 form source and drain regions spanned by a gate structure 186. The gate structure includes a floating gate (FG) 188 and a control gate (CG) 190 separated by intervening barrier layers 192, 194. Data are stored to the cell in relation to the accumulation of electrical charge on the floating gate 188.

The flash memory cells are written (programmed) by applying suitable voltages to migrate charge from the channel to the respective floating gates 188. The presence of charge on the floating gate 188 of a cell increases the threshold voltage that needs to be placed on the control gate 190 to place the cell in a drain-source conductive state. The programmed states are read (sensed) by applying a succession of voltages to the respective drain, source and gate terminals to detect the threshold at which the cells are transitioned to a conductive state along the drain source path (across the channel CH). A special erasure operation is required to remove the accumulated charge and return the cell to an unerased, initialized state.

The flash memory cells may be arranged as single level cells (SLCs) or multi-level cells (MLCs). SLCs store a single bit and MLCs store multiple bits. Generally, each cell can store up to N bits of data by providing 2^{N} distinct accumulated charge levels. At least some of the various rewritable memory constructions of tiers 150, 152 and 154 can also be configured as SLCs or MLCs, depending on the construction and operation of the cells.

It is contemplated that each tier will have its own associated memory storage attributes (e.g., capacity, data unit size, I/O data transfer rates, endurance, etc.). The highest order tier will tend to have the fastest I/O data transfer rate performance (or other suitable performance metric) and the lowest order tier will tend to have the slowest performance. Each of the remaining tiers will have intermediate performance characteristics in a roughly sequential fashion in a priority order.

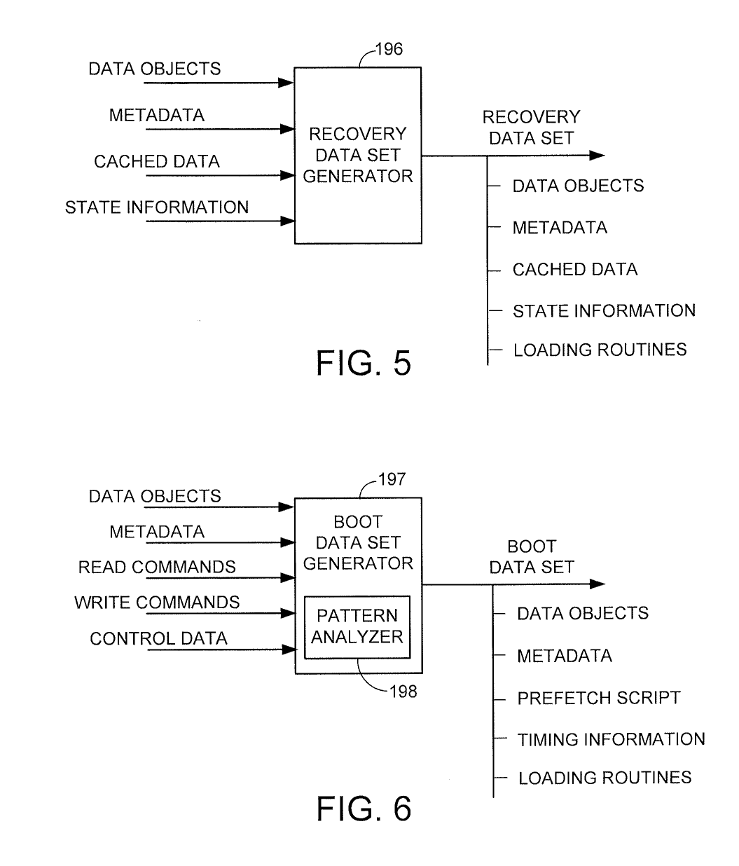

FIG. 5 depicts a recovery data set generator 196 of the restore engine 146 of FIG. 4. The recovery data set generator 196 is operative to generate the recovery data set 128 (FIG. 3) as a representation of the then-existing state of the data storage device 100. The recovery data set may include data objects 112, metadata 114, cached data such as writeback cache data stored in a volatile or non-volatile write buffer pending transfer to the memory structure 104, readback data cached in a read buffer pending transfer to the requestor and/or waiting for potential, speculative cache read hits, state information in the form of parameters, counter values, tables, programming and other control data that currently describe the system.

The recovery data set may include data stored in various memory locations around the storage device, including the data in different discrete memory locations (buffers, caches, memory tiers, tables, latches, etc.). The recovery data set thus represents a “snapshot” of the current state of the device. It follows that loading the recovery data set components to the appropriate memory locations would serve to restore the data storage device to the currently defined state. In some embodiments, the recovery data set further includes loading programs, drivers or other routines that are configured to distribute the various aspects of the substantive content portion of the recovery data set to the correct location(s), as desired.

FIG. 6 shows a boot data set generator 197 of the restore engine 146 of FIG. 4. The boot data set generator 197 operates to generate the boot data set 130. The boot data set 130 represents data used by the device 100 during a data reinitialization (boot) process to restore the device from a deinitialized state to an operationally ready state. The deinitialized state can take a variety of forms, including a hard power down state where the device is turned “off,” an interrupted state, a sleep or hibernation state where the device is moved to a lower power standby mode, a reset state where the device undergoes a soft reboot, etc.

The boot data set generator 197 utilizes a number of inputs to generate the boot data set. Such inputs can include data objects, metadata, read commands, write commands, operational files, programs and other control data.

In some embodiments, a pattern analyzer 198 monitors the device 100 during a power up sequence to observe the sequence of actions taken place during device initialization. The pattern analyzer 198 forms a data structure that identifies various access (read/write) commands issued to and serviced by the device 100 during the boot process. In some cases, the data structure may include the elapsed time intervals between such commands. The data structure may be in the form of a command history table (CHT) that identifies the various commands issued in sequence.

The boot data set may also include some or all of the actual data objects that were the subject of the access commands. For example, if the device initialization process involves the loading and transfer of pre-boot initialization files followed by the loading and transfer of operating system (OS) level files, the various commands and associated programming files or other data sets may be incorporated into the boot data set. Relevant metadata that identify the data objects used during the boot process may also be incorporated into the boot data set in an arrangement that facilitates fast location and retrieval of the associated objects. Other control data used, generated and/or referenced by the device may be included in the boot data set as well.

It will be noted that if the various data objects or other information is subjected to encryption/decryption encoding for purposes of storage footprint reduction or other reasons, the necessary decryption keys may be incorporated or located by the boot data set to enable fast recovery of the data. In other embodiments, non-sensitive data may be stored in a decrypted form to eliminate the need to perform decryption during the boot process.

The data structure (CHT) can be used to form one or more prefetch scripts that indicate the sequence of data objects to be retrieved during the boot process. By executing the prefetch script(s), the device can anticipate and have ready the various data sets required by the device during the boot operation. For clarity, it will be appreciated that the boot operation may operate to place the device 100 itself in an operationally ready condition, may operate to place an associated local user device of which the device 100 forms a part in an operationally ready condition, may operate to place a remote device in an operationally ready condition, or all three (or some of these three) as required.

The recovery data set of FIG. 5 and the boot data set of FIG. 6 are generated at different times during the operation of the device 100, but both are used together to restore the device to an operationally ready state. The boot data set may be generated during an initial boot process experienced by the device, with the pattern analyzer adapted to capture the access pattern sequence used during the boot process. Because the pattern analyzer generally should be operational during the boot sequence, at least data capture portions of the analyzer may need to be incorporated directly into the device pre-boot coding.

Once generated, the boot data set may thereafter be stored in a suitable memory location for future reference during a subsequent boot process. The entire boot data set may be encrypted to reduce storage footprint, provided the boot data set can be subsequently decrypted quickly when needed.

The pattern analyzer 198 subsequently monitors the effectiveness of the boot data set during a subsequent boot process to identify any errors, problems, delays, incorrect or unnecessary data retrievals, etc. that may occur during the subsequent reboot. The boot data set can be adaptively adjusted in response. In some cases, different boot sequences may be carried out under different conditions, such as in the case where multiple different types of OS are loaded to a requestor, different types or levels of initialization are being carried out, etc. For example, transitioning the device from a cold start to normal operation may involve a different sequence as compared to resuming normal operation from a lower power sleep mode. Monitoring the initial stages of the boot process may allow the storage manager 146 to identify and load the appropriate boot data set from a plurality of available boot data sets to support the remainder of the selected boot process.

It is further contemplated that for a given type of boot process, such as from a cold start, some portions of the boot sequence are carried out every time, but other portions vary each time. In such case, only those aspects that remain the same may be stored and incorporated into the boot data set for future use.

In contrast to the boot data set which is pre-generated, the recovery data set is generated “on-the-fly” on an as needed basis. Because the recovery data set will depend on the then-current state of the device 100, the recovery data set will tend to be different each time it is generated. Depending on various factors, a particular recovery data set may be a work in progress; that is, a baseline recovery set may be initially generated and then augmented with different, most-current updates until such time that the final state of the system prior to deinitialization is captured, at which point the recovery data set is completed and ready for use. As with the boot data set, the recovery data set may not encompass all aspects of the state of the system provided such are otherwise readily implemented. For example, programming routines and other states or information loaded by the boot data set need not necessarily be incorporated into the recovery data set since such will already be in place as a result of the execution of the boot data set. Other aspects of the state of the system, such as a current date/time status, inputs from the requestor, etc. can be supplied coincident with or after after the execution of the recovery data set.

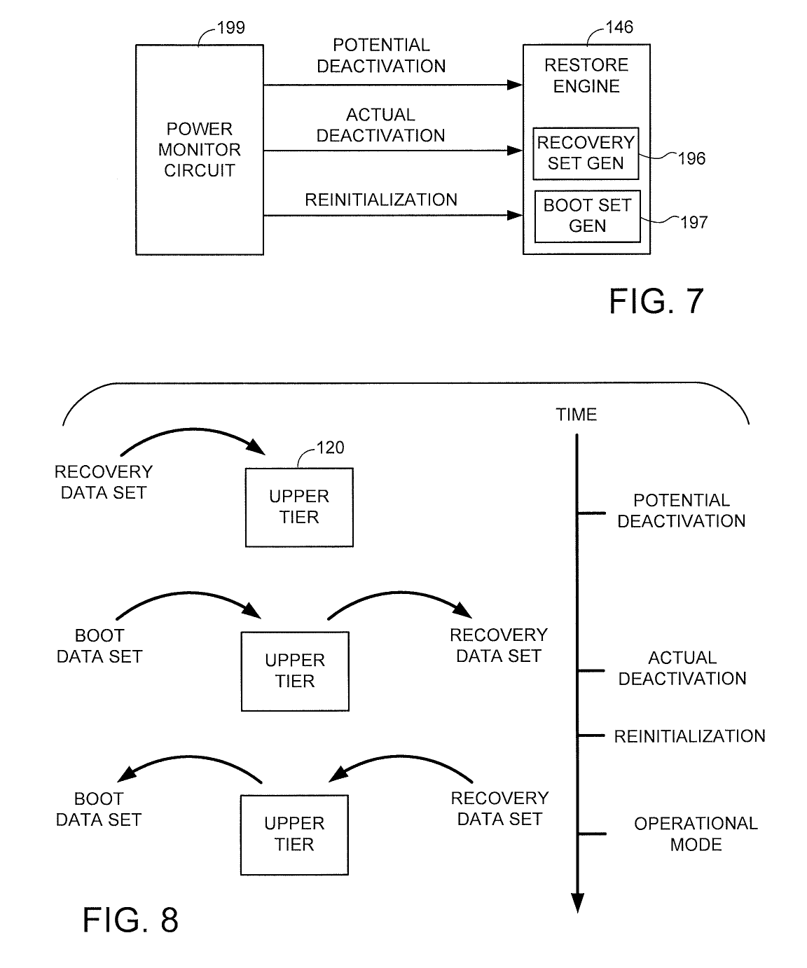

FIG. 7 depicts the restore engine 146 in conjunction with a power monitor circuit 199 of the storage device 100 in accordance with some embodiments. The power monitor circuit 199 can take a variety of forms and is generally configured to detect a variety of potential and actual power states of the device. As shown in FIG. 7, the power monitor circuit 199 provides a variety of signal inputs to the restore engine 146, including a potential deactivation indication signal, an actual deactivation signal and a reinitialization signal. Other signals can be provided as required.

The potential deactivation signal generally indicates that there is a possibility that the device may be powered down or may experience some other anomalous event that temporarily interrupts the continued operation of the device 100 at the normal operational mode level. The interruption may result in a transition of the device to a powered off, low power, sleep or scheduled/unscheduled interruption. This may be carried out via voltage line monitoring, detection of inputs such as shut down/sleep commands issued to the device 100, workload level detection, etc.

The expression of the potential deactivation signal does not necessarily result in an actual deactivation of the device; rather, the potential deactivation signal merely indicates that there is a possibility, based on some criteria, that a power down type event may be experienced in the near future.

The actual deactivation signal, by contrast, signals that a power down event has in fact been initiated to transition the device to a deactivated mode (whether fully powered down, sleep mode, hibernate mode, etc.). The reinitialization signal signals a subsequent command that has been issued, either externally or internally, to return the device 100 to the previous normal operational mode.

For clarity, normal operational mode means an operational state of the device in which the device has sufficient capability to interact with the requestor to service access commands issued to the device in real time. A sleep or hibernate mode leaves some portions of the device in an active state (such as communication circuitry, etc.) but other aspects of the device are turned off or transitioned to a reduced power mode. These latter aspects require being turned back on before the device can resume normal operation.

FIG. 8 is a timing representation indicating different operational aspects of the device 100 during the foregoing states. For purposes of the present example, it will be contemplated that the various data sets are loaded to the first tier 120 shown in FIG. 3. This is merely exemplary and is not limiting, as any number of other memory tiers and/or locations can be used.

Upon receipt by the restore engine 146 of the potential deactivation signal, the engine 146 operates to generate and load the data recovery set to the upper tier 120. The data recovery set may displace and/or incorporate existing data already present in the upper tier, or may occupy another predefined location of the memory adapted for such use. As noted above, the recovery data set represents a snapshot of the current state of the device. The state may be updated as the device continues to operate.

Next, FIG. 8 shows receipt by the restore engine 146 of the actual deactivation signal. At this point, the restore engine 146 executes a data swap by replacing the recovery data set with the boot data set. The boot data set may be overwritten directly onto the recovery data set so that same memory cells are overwritten with new data. The recovery data set may be concurrently transferred to another location, such as but not limited to a lower tier of the memory structure 104 (e.g., the second tier 122 in FIG. 3). Sufficient power will be available to enable the storage manager 140 (FIG. 4) to make these data swaps.

The device then enters the lower power mode as a result of the deactivation of the device. The time during which the device is at this lower power mode will depend on the circumstances; it may be a temporary power down as in the case of a soft or hard reset, it may involve an extended period of time during which the device is off, etc.

At some point the device is reinitialized, as signaled by the reinitialization signal from FIG. 7. The device 100 uses the boot data set resident in the memory tier to execute the boot process to return the device to the normal operational mode. At this point, the recovery data set is swapped back into the memory tier and the device resumes normal operation nominally in the same state as prior to the actual deactivation of the device.

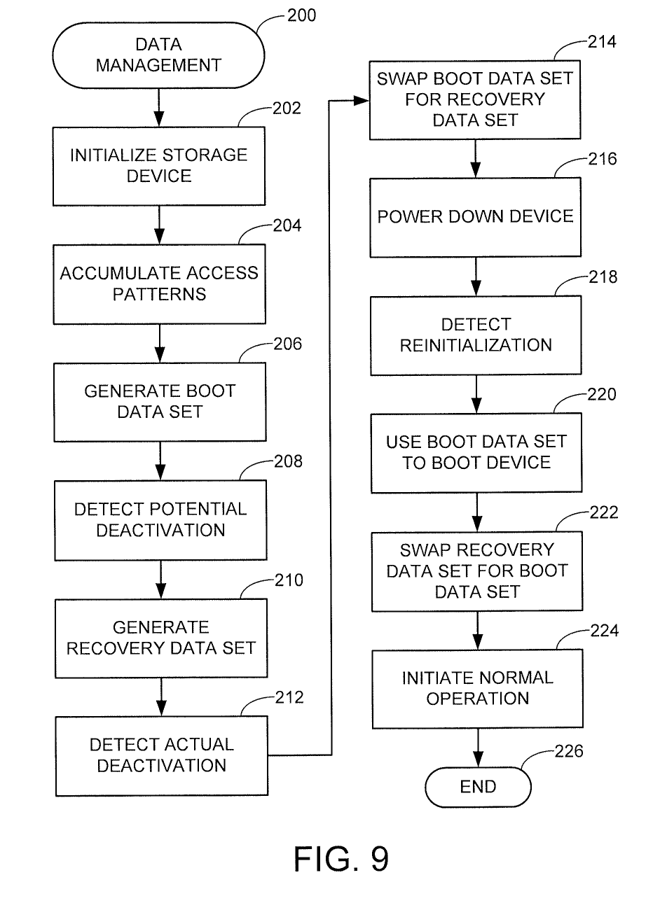

FIG. 9 provides a flow chart for a DATA MANAGEMENT routine 200 illustrative of steps carried out in accordance with various embodiments. The routine will be discussed in the context of a hard power down of the device 100 of FIG. 1, although such is merely illustrative.

The storage device 100 is initialized at step 202. This may involve a boot process as discussed above. During the boot process, access patterns are accumulated at step 204 by the pattern analyzer 198 to generate a boot data set at step 206. The boot data set may include prefetch command scripts, preloaded data, etc. to expedite a subsequent boot process.

The device thereafter enters normal operational mode and services access commands from one or more requestors. A potential deactivation is detected at step 208 by the power monitor circuit 199, signaling a possibility that the device may enter a deactivated state. The form or type of deactivation level (e.g., fully powered down v. sleep mode, etc.) may or may not be known.

In response to the detected potential deactivation, the recovery data set generator 196 generates a recovery data set based on the then-current state of the device 100, step 210. The recovery data set may be updated as access commands continue to be serviced in the interim. If no subsequent deactivation is received within a selected period of time (e.g., 30 seconds, 2 minutes, etc.), the updating of the recovery data set may be aborted and a detected potential deactivation window that was initiated by the potential deactivation signal may expire.

As shown in FIG. 9, however, an actual deactivation event is detected at step 212, which results in the finalization of the recovery data set and the swapping of the boot data set for the recovery data set at step 214. As noted above, this does two things in preparation for subsequent reinitialization of the device: it prepares for expedited booting via the boot data set and it prepares for expedited recovery of the prior state via the recovery data set. The device 100 then enters the lower powered mode (in this case, powered off) at step 216.

At some point in the future, whether immediately or after an extended period of time, reinitialization of the device is detected at step 218. The device 100 commences a boot sequence using the boot data set at step 220 to return the device to a normal operational state. The recovery data set is swapped into the memory location in place of the boot data set at step 222 to recover the previous most-current state of the device prior to power down, and system operation is resumed from that state at step 224.

The routine then ends at 226, although it will be appreciated that the routine may loop back to step 208 upon a subsequent potential deactivation event. Moreover, although not shown in FIG. 9, it will be appreciated that step 204 may be repeated during step 220 to ensure efficacy of the generated boot data set and, as desired, changes or updates may be made thereto and stored for future use.

The respective recovery data set and boot data set can take any suitable forms to support the foregoing operations. As desired, the data sets can include scripts that direct swapping of the respective sets when the ends of the respective data sets are reached. For example, the generated recovery data set can be configured to execute the data swap of the boot data set responsive to the actual deactivation signal, and the boot data set can, in turn, be configured to execute the data swap of the recovery data set at the conclusion of the boot process.

Numerous characteristics and advantages of various embodiments of the present disclosure have been set forth in the foregoing description, together with structural and functional details. Nevertheless, this detailed description is illustrative only, and changes may be made in detail, especially in matters of structure and arrangements of parts within the principles of the present disclosure to the full extent indicated by the broad general meaning of the terms in which the appended claims are expressed.

What is claimed is:

1. A method comprising:
storing a recovery data set in a rewritable non-volatile memory responsive to detection of a potentially imminent deactivation of a storage device, the recovery data set representing a current state of the device;
swapping the recovery data set with the boot data set in said memory responsive to subsequent deactivation of the device;
using the boot data set in said memory to transition the device from a deactivated mode to an operationally ready mode; and
swapping the boot data set with the recovery data set in said memory to return the device to the current state after said transition to the operationally ready mode.

2. The method of claim 1, in which the recovery data set is generated responsive to a detected potential deactivation of the storage device and comprises data and commands that describe the current state of the device.

3. The method of claim 2, in which the recovery data set comprises a command to swap the boot data set for the recovery data set responsive to a subsequent detection of an actual deactivation of the storage device.

4. The method of claim 1, in which the recovery data set is loaded to an upper tier of a multi-tier memory structure comprising a plurality of non-volatile memory tiers in a priority order, each of the tiers having different data transfer rates and memory cell construction types, and in which the boot data set is overwritten onto the recovery data set in said upper tier during the first swapping step.

5. The method of claim 1, in which the boot data set is generated responsive to detected access patterns during a previous initialization of the device and comprises data and commands used during a boot sequence to transition the device to the operationally ready state.

6. The method of claim 1, in which the boot data set comprises an operational file loaded to the memory from another memory in anticipation of a request for the operational file by a requestor during the transitioning of the device from the deactivated mode to the operationally ready mode

7. The method of claim 1, in which the boot data set is loaded to a selected location in the non-volatile memory responsive to an actual deactivation signal and the loaded boot data set is used by the device during a subsequent boot process to prefetch data transferred during the subsequent boot process.

8. The method of claim 7, in which the recovery data set is subsequently loaded to the selected location at a conclusion of the subsequent boot process to resume operation of the device in said normal operational mode.

9. The method of claim 1, in which the recovery data set is generated as a baseline data set responsive to a potential deactivation signal indicating said potentially imminent deactivation of the device, the recovery data set augmented with updates that reflect changes in a state of the system over a period of time between receipt of the potential deactivation signal and receipt of a subsequent actual deactivation signal to provide a final recovery data set, and wherein the method further comprises storing the final recovery data set in a non-volatile memory, the final recovery data set replacing the boot data set after said transitioning of the device from the deactivated mode to the operationally ready mode.

10. An apparatus comprising:
a multi-tier memory structure comprising a plurality of non-volatile memory tiers each having different data transfer attributes and corresponding memory cell constructions; and
a storage manager adapted to generate a boot data set comprising data and commands used by the device during a boot sequence and to generate a recovery data set comprising data and commands that describe a current state of the device, the storage manager adapted to load the boot data set to a selected location in the memory structure responsive to a deactivation signal and to swap the boot data set with the recovery data set after use of the loaded boot data set to restore the device to the selected state.

11. The apparatus of claim 10, in which the selected location in the memory structure comprises an upper memory tier, and wherein the recovery data set is overwritten onto the boot data set in the upper memory tier.

12. The apparatus of claim 10, in which the storage manager generates the boot data set during a previously executed boot sequence to transition the device to a normal operational mode by monitoring access commands issued to the device by a requestor.

13. The apparatus of claim 12, in which the boot data set comprises a prefetch command script that requests transfer of prefetched data from a lower tier to an upper tier of the memory structure in anticipation of requests for said prefetched data by the requestor.

14. The apparatus of claim 10, in which the recovery data set is generated as a baseline data set responsive to a potential deactivation signal indicating a potentially imminent deactivation of the device, the recovery data set augmented with updates that reflect changes in a state of the system over a period of time between receipt of the potential deactivation signal and receipt of a subsequent actual deactivation signal to provide a final recovery data set, and wherein the storage manager stores the final recovery data set in a lower tier of the memory structure and migrates a copy of the final recovery data set to an upper tier of the memory structure to replace the boot data set after transitioning of the device from a deactivated mode to the normal operational mode.

15. The apparatus of claim 10, further comprising a power monitor circuit which generates a potential deactivation signal indicative of an imminent deactivation of the device, wherein the storage manager generates the recovery data set responsive to receipt of the potential deactivation signal.

16. The apparatus of claim 15, in which the power monitor circuit further generates an actual deactivation signal indicative of commencement of an actual deactivation of the device, wherein the storage manager loads the boot data set to an upper memory tier of the memory structure responsive to receipt of the actual deactivation signal.

17. The apparatus of claim 16, in which the power monitor circuit further generates a reinitialization signal indicative of commencement of reinitialization of the device, wherein the storage manager uses the loaded boot data set to execute a boot sequence to return the device to the normal operational mode responsive to receipt of the reinitialization signal and, at a conclusion of the boot sequence, loads the recovery data set to the upper memory tier to return the device to the selected state.

18. An apparatus comprising:
a multi-tier memory structure comprising a plurality of non-volatile memory tiers each having different data transfer attributes and corresponding memory cell constructions, the tiers arranged in a priority order;
a power monitor circuit adapted to generate a potential deactivation signal indicative of a potentially imminent deactivation of the device, an actual deactivation signal indicative of an actual deactivation of the device and a reinitialization signal indicative of a reinitialization of the device; and
a storage manager adapted to generate and store in the memory structure a recovery data set responsive to the potential deactivation signal, to load in the memory structure a boot data set responsive to the actual deactivation signal, and to swap the boot data set with the recovery data set responsive to the reinitialization signal.

19. The apparatus of claim 18, in which the boot data set comprises data and commands used by the device during a boot sequence to transition the device from a deinitialized mode to a normal operational mode during reinitialization of the device.

20. The apparatus of claim 18, in which the recovery data set comprises data and commands to restore the device to a then-current state prior to actual deinitialization of the device.
